(19) United States
(12) Patent Application Publication
(10) Pub. No.: US 2025/0004501 A1
(43) Pub. Date: Jan. 2, 2025

(54) SEALED COMPONENTS FOR HEAT MANAGEMENT AND GROUNDING

(71) Applicant: Apple Inc., Cupertino, CA (US)

(72) Inventors: Ritu SHAH, Sunnyvale, CA (US); Edward S. HUO, Sunnyvale, CA (US); Anthony S. MONTEVIRGEN, Redwood City, CA (US)

(21) Appl. No.: 18/693,140

(22) PCT Filed: Sep. 16, 2022
(86) PCT No.: PCT/US2022/043881

§ 371 Date: Mar. 18, 2024

Related U.S. Application Data
(60) Provisional application No. 63/247,634, filed on Sep. 23, 2021.

(51) Int. Cl. G06F 1/16; H05K 7/20

(52) U.S. Cl. CPC G06F 1/163; H05K 7/2039

(57) ABSTRACT

A head-mountable device (100) can include electronic circuits, such as cameras (150, 350, 450), sensors (170), and input/output devices. The head-mountable device can secure such electronic circuits with an assembly that also provides thermal dissipation, electrical grounding, and a sealed chamber (312, 412) to isolate the electronic circuit from ingress of debris. The assembly can provide a degree of mobility, where desired. Accordingly, the electronic circuit can operate more optimally and with lower risk of degradation and interference with other components of the head-mountable device.

### CROSS-REFERENCE TO RELATED APPLICATION

This application claims the benefit of U.S. Provisional Application No. 63/247,634, entitled “HEAD-MOUNTABLE DEVICE WITH SEALED COMPONENTS FOR HEAT MANAGEMENT AND GROUNDING,” filed Sep. 23, 2021, the entirety of which is incorporated herein by reference.

### TECHNICAL FIELD

The present description relates generally to head-mountable devices, and, more particularly, to head-mountable devices having sealed components for heat management and grounding.

### BACKGROUND

A head-mountable device can be worn by a user to display visual information within the field of view of the user. The head-mountable device can be used as a virtual reality (VR) system, an augmented reality (AR) system, and/or a mixed reality (MR) system. A user may observe outputs provided by the head-mountable device, such as visual information provided on a display. The display can optionally allow a user to observe an environment outside of the head-mountable device. Other outputs provided by the head-mountable device can include speaker output and/or haptic feedback. A user may further interact with the head-mountable device by providing inputs for processing by one or more components of the head-mountable device. For example, the user can provide tactile inputs, voice commands, and other inputs while the device is mounted to the user's head.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates a top view of a head-mountable device, according to some embodiments of the present disclosure.

FIG. 2 illustrates a plan view of an assembly having a component secured to a thermally conductive bracket, according to some embodiments of the present disclosure.

FIG. 3 illustrates a sectional view of a portion of the assembly of FIG. 2, according to some embodiments of the present disclosure.

FIG. 4 illustrates a plan view of an assembly having a component secured to a thermally conductive bracket, according to some embodiments of the present disclosure.

FIG. 5 illustrates a sectional view of a portion of the assembly of FIG. 4 taken along line A-A, according to some embodiments of the present disclosure.

FIG. 6 illustrates another sectional view of a portion of the assembly of FIG. 4 taken along line B-B, according to some embodiments of the present disclosure.

FIG. 7 illustrates a sectional view of an assembly, according to some embodiments of the present disclosure.

FIG. 8 illustrates a block diagram of a head-mountable device, in accordance with some embodiments of the present disclosure.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

Head-mountable devices, such as head-mountable displays, headsets, visors, smartglasses, head-up display, etc., can perform a range of functions that are managed by the components (e.g., sensors, circuitry, and other hardware) included with the wearable device.

There are many thermal components of a head-mountable device that generate significant heat that is required to be dissipated in order to maximize component lifetime. These include cameras, sensors, light emitters, laser modules, and other heat generating components. Managing the temperature of such components can be important to maintain the service life and performance specifications of the component. In most thermal designs, the heat from the component is expelled through a large thermal mass, typically the frame or another system component, by a thermal interface material. Most designs assume the two components have very small movement relative to each other (<0.5 mm), and therefore most semi-compliant or hard thermal interfaces work to remove the heat from the component. However, in some mechanical designs, some components move significantly relative to the large thermal mass in the system and cannot be cooled by typical convection due to airflow constraints. As such, it can be beneficial to provide a heat sinking method to remove heat from a thermal generating component through conduction that moves with respect to all other system components.

Additionally, many electronic circuits, such as cameras, are also optically sensitive and perform best when a dust-free chamber is maintained in front of the optics in order to maximize optical performance. Some cameras and/or sensors are unable to maintain traditional seals due to sensitive optical components.

Additionally, some electronic circuits, such as cameras, perform best when grounded in multiple locations in order to prevent noise from radiating into other parts of the head-mountable device. Such noise can adversely impact the performance of antennas and other electrical components at certain frequencies and intensities. Furthermore, a metal bodies of a camera can act as an antenna, thereby causing further electromagnetic interference by radiation.

Embodiments of the present disclosure provide a head-mountable device with electronic circuits, such as cameras, sensors, and input/output devices. The head-mountable device can secure such electronic circuits with an assembly that also provides thermal dissipation, electrical grounding, and a sealed chamber to isolate the electronic circuit from ingress of debris. The assembly can provide a degree of mobility, where desired. Accordingly, the electronic circuit can operate more optimally and with lower risk of degradation and interference with other components of the head-mountable device.

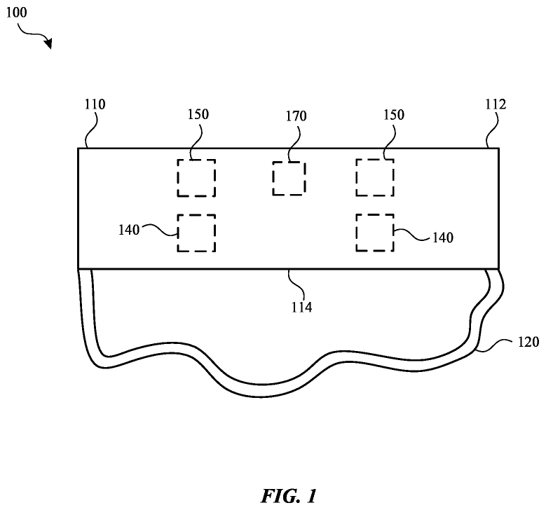

These and other embodiments are discussed below with reference to FIGS. 1-8. However, those skilled in the art will readily appreciate that the detailed description given herein with respect to these Figures is for explanatory purposes only and should not be construed as limiting.

According to some embodiments, for example as shown in FIG. 1, a head-mountable device 100 with a chassis 110 that is worn on a head of a user. The chassis 110 can provide structure around a peripheral region thereof to support any internal components of the chassis 110 in their assembled position. For example, the chassis 110 can enclose and support various internal components (including for example integrated circuit chips, processors, memory devices and other circuitry) to provide computing and functional operations for the head-mountable device 100, as discussed further herein.

The chassis 110 can be supported on a user's head with a head engager 120. The head engager 120 can wrap or extend along opposing sides of a user's head and/or to a rear of the user's head. The head engager 120 can optionally include earpieces for wrapping around or otherwise engaging or resting on a user's ears. It will be appreciated that other configurations can be applied for securing the head-mountable device 100 to a user's head. For example, one or more bands, straps, belts, caps, hats, or other components can be used in addition to or in place of the illustrated head engager 120 of the head-mountable device 100. The head engager 120 can optionally include a band for extending to and/or about a rear side of the head of the user. The head engager 120 can optionally extend from the chassis 110 or another component coupled to the chassis 110. The band can be stretchable to comfortably provide tension about the head of the user. The head engager can further include an adjuster (not shown) for adjusting a tightness and/or fit of the head engager.

While several components are shown within the chassis 110, it will be understood that some or all of these components can be located anywhere within or on the head-mountable device 100. For example, one or more of these components can be positioned within the chassis 110 and/or a head engager 120 of the head-mountable device 100. The chassis 110 can be positioned in front of the eyes of a user to provide information within a field of view of the user. The chassis 110 can provide a nosepiece to rest on a user's nose.

The chassis 110 can include and/or support one or more cameras 150. The cameras 150 can be positioned on or near an outer side 112 of the chassis 110 to capture images of views external to the head-mountable device 100. As used herein, an outer side of a portion of a head-mountable device is a side that faces away from the user and/or towards an external environment. The captured images can be used for display to the user or stored for any other purpose. Each of the cameras 150 can be movable along the outer side 112. For example, a track or other guide can be provided for facilitating movement of the camera 150 therein.

The head-mountable device 100 can include displays 140 that provide visual output for viewing by a user wearing the head-mountable device 100. One or more displays 140 can be positioned on or near an inner side 114 of the chassis 110. As used herein, an inner side 114 of a portion of a head-mountable device is a side that faces toward the user and/or away from the external environment. A display 140 can transmit light from a physical environment (e.g., as captured by a camera) for viewing by the user. Such a display 140 can include optical properties, such as lenses for vision correction based on incoming light from the physical environment. Additionally or alternatively, a display 140 can provide information as a display within a field of view of the user. Such information can be provided to the exclusion of a view of a physical environment or in addition to (e.g., overlaid with) a physical environment.

A physical environment refers to a physical world that people can interact with and/or sense without necessarily requiring the aid of an electronic device. A computer-generated reality environment relates to a partially or wholly simulated environment that people sense and/or interact with the assistance of an electronic device. Examples of computer-generated reality include, but are not limited to, mixed reality and virtual reality. Examples of mixed realities can include augmented reality and augmented virtuality. Examples of electronic devices that enable a person to sense and/or interact with various computer-generated reality environments include head-mountable devices, projection-based devices, heads-up displays (HUDs), vehicle windshields having integrated display capability, windows having integrated display capability, displays formed as lenses designed to be placed on a person's eyes (e.g., similar to contact lenses), headphones/earphones, speaker arrays, input devices (e.g., wearable or handheld controllers with or without haptic feedback), smartphones, tablets, and desktop/laptop computers. A head-mountable device can have an integrated opaque display, have a transparent or translucent display, or be configured to accept an external opaque display from another device (e.g., smartphone).

Each display 140 can be adjusted to align with a corresponding eye of the user. For example, each display 140 can be moved along one or more axes until a center of each display 140 is aligned with a center of the corresponding eye. Accordingly, the distance between the displays 140 can be set based on an interpupillary distance (“IPD”) of the user. IPD is defined as the distance between the centers of the pupils of a user's eyes.

The head-mountable device 100 can include one or more sensors 170, as described herein. The head-mountable device 100 can include one or more other sensors. Such sensors can be configured to sense substantially any type of characteristic such as, but not limited to, images, pressure, light, touch, force, temperature, position, motion, and so on. For example, the sensor can be a photodetector, a temperature sensor, a light or optical sensor, an atmospheric pressure sensor, a humidity sensor, a magnet, a gyroscope, an accelerometer, a chemical sensor, an ozone sensor, a particulate count sensor, and so on. By further example, the sensor can be a bio-sensor for tracking biometric characteristics, such as health and activity metrics. Other user sensors can perform facial feature detection, facial movement detection, facial recognition, eye tracking, user mood detection, user emotion detection, voice detection, etc. Sensors can include a camera which can capture image-based content of the outside world.

The electronic circuits (e.g., cameras 150, sensors 170, input/output devices, and/or other electronic circuits) can be securely housed within the head-mountable device. Such an assembly can provide protection, thermal mitigation, and electrical grounding as needed to the electronic circuits.

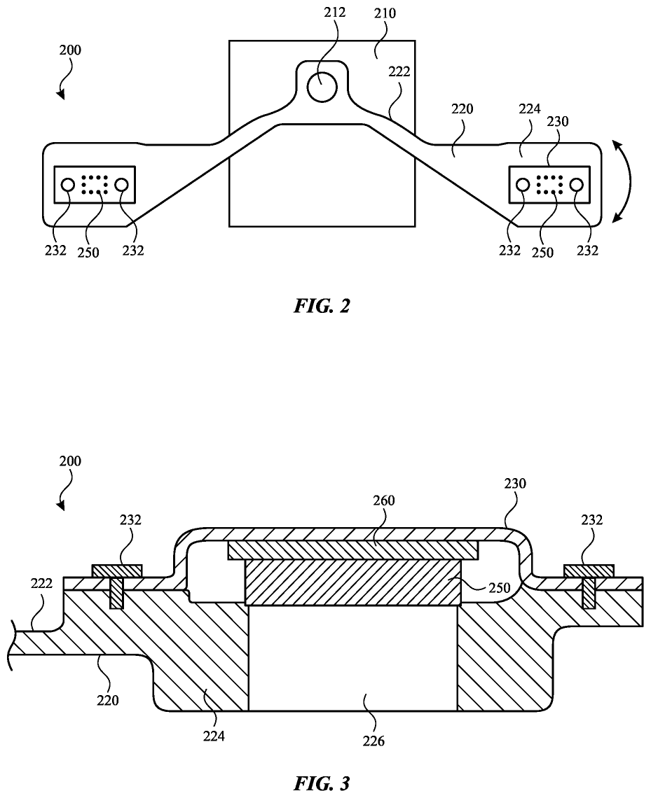

Referring now to FIGS. 2 and 3, an electronic circuit of a head-mountable device can be provided with thermal dissipation as well as a range of mobility. In some embodiments, an assembly 200 can support an electronic circuit 250 to provide thermal dissipation as well as a range of mobility. The electronic circuit 250 can be any electronic circuit of a head-mountable device, including the camera 150, the sensor 170, an input/output device, and/or another electronic circuit of the head-mountable device 100 of FIG. 1. As such, the illustrated assembly 200 can support the electronic circuit 250 on a chassis 210, which can correspond to the chassis 110 shown in FIG. 1.

The assembly 200 can include a bracket 220 moveably coupled to the chassis 210. For example, the bracket 220 can be coupled to the chassis 210 by a pivot or other mechanism that provides a range of relative motion between the bracket 220 and the chassis 210. As shown in FIG. 2, the bracket 220 can rotate by pivoting about the pivot 212. Additionally or alternatively, the bracket 220 can undergo translational motion with respect to the chassis 210. The motion of the bracket 220 can provide the electronic circuit 250 mounted thereon with a range of motion with respect to the chassis 210 and/or other components of the head-mountable device. For example, the range can be up to 5 mm of motion by the bracket 220 relative to the chassis 210 and/or other components. Such motion can enhance operation of the electronic circuit 250. By further example, the motion of the bracket 220 with respect the chassis 210 can dampen the effect of external forces applied to the electronic circuit 250, such as during impact following a drop event of the head-mountable device. As such, the motion can protect the electronic circuit 250 from excessive forces and thereby prolong its service life.

By providing relative motion between the bracket 220 and the chassis 210, the opportunity for thermal dissipation into the chassis 210 is significantly reduced in order to facilitate such motion. As such, the bracket 220 can be provided with features that facilitate heat thermal dissipation therein adequate to facilitate proper operation of the electronic circuit 250. For example, as shown in FIGS. 2 and 3, the electronic circuit 250 can be mounted to an end portion 224 of the bracket 220. Such an end portion 224 can be coupled to the pivot 212 by an arm 222, which extends a distance away from the pivot 212. The end portion 224 can provide a significant thermal mass to act as a heat sink that draws heat away from the electronic circuit 250. For example, the end portion 224 can have a thickness that is greater than a thickness of the arm 222. Such a thickness can be measured in any one of multiple dimensions. In contrast to the end portion 224, the arm 222 can have a relatively smaller thickness to minimize overall weight of the bracket 220.

While the electronic circuit 250 can be coupled to the bracket 220 (e.g., at the end portion 224) on one side thereof, the electronic circuit 250 can further be engaged on an opposing side thereof to further enhance thermal dissipation. For example, the assembly 200 can further include a cover 230 that extends over a side of the electronic circuit 250. The cover 230 can further be coupled to the bracket, for example at the end portion 224. As shown in FIG. 3, one or more fasteners 232 can be provided to couple the cover 230 to the bracket 220. The cover 230 can provide thermal dissipation properties to draw heat away from the electronic circuit 250 and into the bracket 220.

In some embodiments, the cover 230 can include a plate, for example of one or more metal materials that provide both high thermal conductivity and stiffness. For example, the cover 230 can include a clad stiffener with outer layers and an inner layer that provide both rigidity and thermal conductivity. For example, the outer layers can include stainless steel or another material (e.g., metal) that has higher rigidity than a material of the inner layer. The inner layer can include aluminum, copper, or another material (e.g., metal) that has higher thermal conductivity than a material of the outer layer.

In some embodiments, the cover 230 can include a sheet that provides thermal conductivity. For example, the cover 230 can include a sheet, tape, weave, fabric film, or other structure that extends across at least one side of the electronic circuit 250 and is coupled to the bracket 220. Such a cover 230 can be of a material, such as graphite, that provides thermal dissipation as well as conformity to the electronic circuit 250. It will be understood that, in such an embodiment, the cover 230 can be relatively flexible but provide adequate support by being placed under tension across the electronic circuit 250. Such a cover 230 can be securely coupled to the bracket 220, such as with an adhesive.

Additionally, a thermally conductive medium 260 can be provided between the electronic circuit 250 and of the cover 230. For example, the can thermally conductive medium 260 can include a thermal gel having high thermal conductivity. The thermally conductive medium 260 can have broad engagement across both the cover 230 and the electronic circuit 250 to maximize the efficiency of thermal dissipation.

Accordingly, heat generated by the electronic circuit 250 can be dissipated both directly into the bracket 220 (e.g., at the end portion 224 on one side of the electronic circuit 250) and through a thermally conductive medium 260 and/or a cover 230 220 (e.g., on an opposite side of the electronic circuit 250) into the bracket 220. The thermal mass of the bracket 220, particularly at the end portion 224, can provide adequate thermal dissipation capabilities, thereby reducing the need to further dissipate the heat into the chassis 210 (e.g., via the pivot 212).

Will be understood that the electronic circuit 250 can be any type of heat generating device. Where the electronic circuit 250 is a device that receives input or provides output, the bracket 220 can provide a channel 226, through which the electronic circuit 250 can perform one or more operations. For example, where the electronic circuit 250 is a light projector, like can be admitted from the electronic circuit 250 through the channel 226. By further example, where the electronic circuit 250 is a camera, light can be transmitted through the channel 226 and to a sensor of the electronic circuit 250.

Accordingly, the assembly 200 can provide a structural, thermally conductive bracket 220 that holds the electronic circuit 250 and acts as a thermal mass. The bracket 220 can then dissipate heat to the chassis 210 while still providing motion capabilities to the electronic circuit 250. As such, an electronic circuit 250 can generate heat (e.g., output for example, 250 mW of power) while still maintaining a temperature of below 50° C. in a 40° C. ambient temperature. Such an assembly does not require the bracket 220 holding the electronic circuit 250 to be fixed to the chassis 210, but rather allows more free mechanical design and ensures there are no constraints holding the electronic circuit 250 to another element in the head-mountable device. This freedom of motion can be useful when trying to isolate the bracket 220 itself from the system during a drop event. The heat dissipation mechanisms can be very low profile and add little mass to the head-mountable device.

Referring now to FIGS. 4-6, an electronic circuit of a head-mountable device can be provided with thermal dissipation as well as a sealed chamber for protection from ingress of debris. In some embodiments, an assembly 300 can support an electronic circuit 350 to provide thermal dissipation as well as a sealed chamber. The electronic circuit 350 can be any electronic circuit of a head-mountable device, including the camera 150, the sensor 170, an input/output device, and/or another electronic circuit of the head-mountable device 100 of FIG. 1. As such, the illustrated assembly 300 can support the electronic circuit 350 on a chassis 310, which can correspond to the chassis 110 shown in FIG. 1.

As shown in FIG. 4, the assembly 300 can include a chassis 310 with an electronic circuit 350 positioned therein. A sheet 330 can cover the electronic circuit 350 and extend across both a flex circuit 340 and a portion of the chassis 310, where the sheet 330 can be securely coupled thereto.

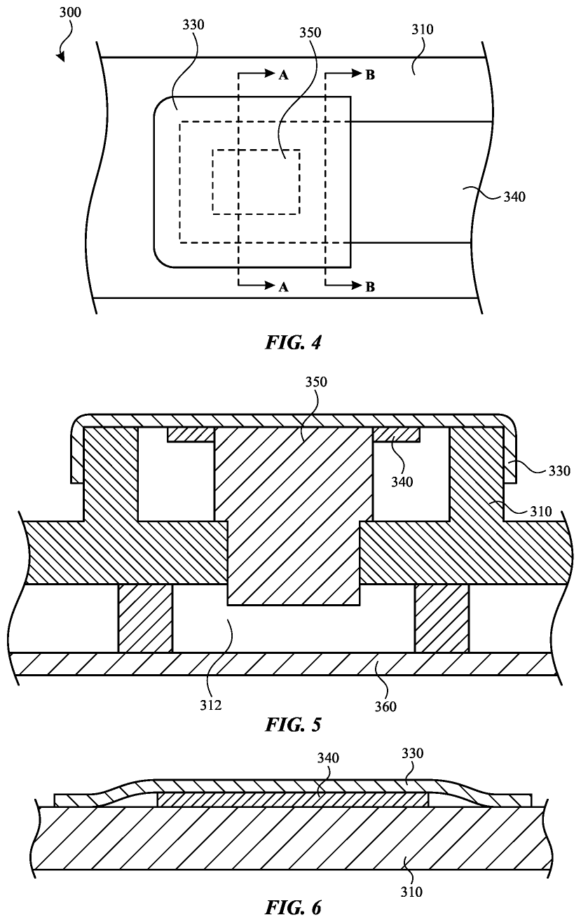

As shown in FIG. 5, the chassis 310 as well as other components can define a sealed chamber 312. At one end of the sealed chamber 312, a window 360 can be provided to allow the electronic circuit 350 to receive inputs or provide output. For example, the electronic circuit 350 can be a camera that captures a view through the window 360.

The sheet 330 can be a thermally conductive tape, fabric, or film to both dissipate heat from the module into a larger thermal mass and to maintain a seal around the chamber 312. By sealing the chamber 312, dust or other debris ingress is prevented into the optical cavity in front of the electronic circuit 350. This can improve performance of the electronic circuit 350, such as where the electronic circuit 350 is a camera. The thermally conductive sheet 330 can contact the electronic circuit 350 in heat sensitive areas and avoid touching other sensitive components. The sheet 330 can be coupled to the chassis 310 to seal around the electronic circuit 350. For example, the sheet 330 can contact the chassis 310 on multiple sides of the electronic circuit 350, including opposing sides of the electronic circuit 350. Where the outer periphery of the sheet 330 is not coupled to the chassis 310, it can be coupled to the flex circuit 340.

The sheet 330 can also provide thermal dissipation to the chassis 310. For example, regardless of thermal dissipation on other sides of the electronic circuit 350, the sheet 330 can provide the most thermally efficient pathway on a particular (e.g., top) side of the electronic circuit 350. As such, the sheet 330 can and also works to attach onto a thermal mass and conduct heat away from the module and into another component to reduce module temperature.

In some embodiments, the sheet 330 can be formed as a sheet, tape, weave, fabric, film, or other structure that extends across at least one side of the electronic circuit 350 and is coupled to the chassis 310. Such a sheet 330 can be of a material, such as graphite, that provides thermal dissipation as well as conformity to the electronic circuit 250. It will be understood that, in such an embodiment, the sheet 330 can be relatively flexible but provide adequate support by being placed under tension across the electronic circuit 350 and/or the flex circuit 340. Such a sheet 330 can be securely coupled to the chassis 310, such as with an adhesive. In some embodiments, the sheet 330 has a thermal conductivity of at least 200 W/(m·K), 300 W/(m·K), 400 W/(m·K), 500 W/(m·K) 600 W/(m·K), and the like.

As shown in FIG. 6, a flex circuit 340 can extend out of the chamber 312 for operably connecting the electronic circuit 350 to control circuitry (e.g., a processor). As used herein, “flexible circuit” or “flex circuit” is a structure that includes a conductive layer, an insulation layer, and optionally a substrate layer. A flex circuit can be provided in electrical communication with at least one electrode, terminal, and/or connector. A flex circuit is generally flexible, such that it can conform to contours of other components. The flex circuit 340 can bend and/or flex to maintain an operable connection throughout a range of motion of nearby and/or connected components.

As further shown in FIG. 6, the sheet 330 can extend to cover at least a portion of the flex circuit 340. The sheet 330 can be coupled to the chassis 310 to seal around the flex circuit 340. Accordingly, the sheet 330 can be positioned against the electronic circuit 350, the flex circuit 340, and the chassis 310. As such, the sheet 330 can form a seal at a side of the chamber 312 (e.g., opposite the window 360).

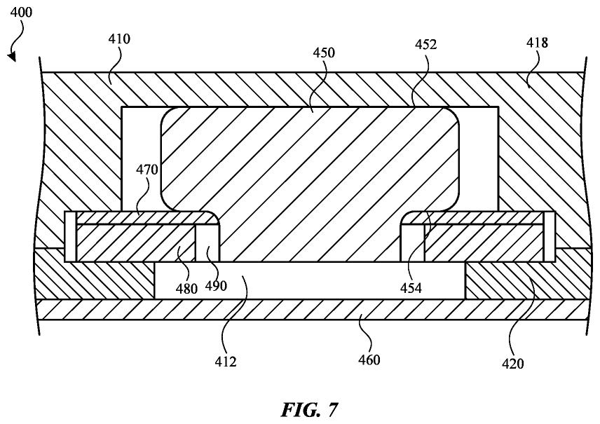

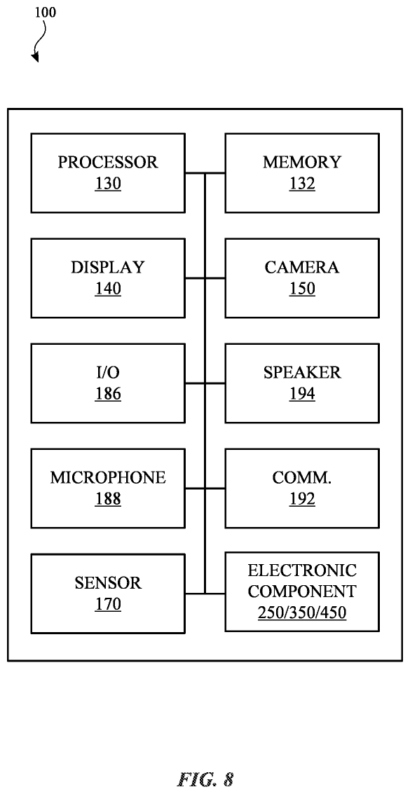

Referring now to FIG. 7, an electronic circuit of a head-mountable device can be provided with adequate electrical grounding as well as a sealed chamber for protection from ingress of debris. In some embodiments, an assembly 400 can support an electronic circuit 450 to provide thermal dissipation as well as a sealed chamber. The electronic circuit 450 can be any electronic circuit of a head-mountable device, including the camera 150, the sensor 170, an input/output device, and/or another electronic circuit of the head-mountable device 100 of FIG. 1. As such, the illustrated assembly 400 can support the electronic circuit 450 on a chassis 410, which can correspond to the chassis 110 shown in FIG. 1.

As shown in FIG. 7, the assembly 400 can include a chassis 410 with an electronic circuit 450 positioned therein. The chassis 410 as well as other components can define a sealed chamber 412. At one end of the sealed chamber 412, a window 460 can be provided to allow the electronic circuit 450 to receive inputs or provide output. For example, the electronic circuit 450 can be a camera that captures a view through the window 460. In some embodiments, the window 460 can be omitted and the electronic circuit 450 can provide its own sealed chamber for sub-components stored therein.

A first chassis portion 418 can engage the electronic circuit 450 on a first side 452 thereof. The first chassis portion 418 can provide electrical conductivity to provide a pathway to ground for the electronic circuit 450. It will be understood that it can be beneficial to provide multiple points of grounding to an electronic circuit, so that the electrical pathways are broadly distributed and balanced.

As shown in FIG. 7, the electronic circuit 450 can be biased against the chassis 410 (e.g., at the first chassis portion 418) by an elastic member 480. The elastic member 480 can be positioned at a side of the electronic circuit 450 that is opposite the first chassis portion 418.

The electrically conductive plate 470 can engage the electronic circuit 450 on a second side 454 thereof, opposite the first side 452. The elastic member 480 can bias the electrically conductive plate 470 against the electronic circuit 450, for example at the second side 454. For example, the elastic member 480 can be a foam structure, an elastomer, a matrix material, or another material having elastic properties. The elastic member 480 can include a pressure-sensitive adhesive that is activated upon compression. A portion of each of the elastic member 480 and the electrically conductive plate 470 can be positioned between the first chassis portion 418 and a second chassis portion 420. The elastic member 480 can expand or otherwise be biased to engage both the electrically conductive plate 470 and the second chassis portion 420.

The electrically conductive plate 470 and/or the elastic member 480 can form an annular shape or otherwise form a channel 490 into which the electronic circuit 450 can at least partially extend. By further example, the electronic circuit 450 can receive inputs or provide outputs through the channel 490, the chamber 412, and/or the window 460. For example, the electronic circuit 450 can be a camera that captures a view through the channel 490, the chamber 412, and/or the window 460.

The electrically conductive plate 470 can provide electrical conductivity to provide a pathway to ground for the electronic circuit 450 through the second side 454. As such, the electrically conductive plate 470 and the chassis 410 (e.g., at the first chassis portion 418) can provide multiple, broadly distributed points of grounding to the electronic circuit 450. Furthermore, the electrically conductive plate 470 can provide efficient electrical pathways that the elastic member 480 alone would. For example, the electrically conductive plate 470 can provide a structure and material that is more electrically conductive that a foam or other structure of the elastic member 480. By further example, the electrically conductive plate 470 can include aluminum, copper, or another material (e.g., metal) that has higher electrical conductivity than a material of the elastic member 480.

As such, the chassis 410 and the electrically conductive plate 470 provides ground connections for the electronic circuit 450 to prevent against the module radiating noise to the rest of the head-mountable device (e.g., to antennas, other sensors, etc.). The elastic member 480 makes contact between the electronic circuit 450 and the chassis 410 and the window 460 provides a dust seal between the electronic circuit 450 and the chassis 410. The ground connection at the electrically conductive plate 470 can be better than would be provided by adhesive or the elastic member 480.

Referring now to FIG. 3, components of the head-mountable device can be operably connected to provide the performance described herein. FIG. 8 shows a simplified block diagram of an illustrative head-mountable device 100 in accordance with one embodiment of the invention. It will be appreciated that components described herein can be provided on one, some, or all of a chassis and/or a head engager. It will be understood that additional components, different components, or fewer components than those illustrated may be utilized within the scope of the subject disclosure.

As shown in FIG. 8, the head-mountable device 100 can include a processor 130 (e.g., control circuitry) with one or more processing units that include or are configured to access a memory 132 having instructions stored thereon. The instructions or computer programs may be configured to perform one or more of the operations or functions described with respect to the head-mountable device 100. The processor 130 can be implemented as any electronic device capable of processing, receiving, or transmitting data or instructions. For example, the processor 130 may include one or more of: a microprocessor, a central processing unit (CPU), an application-specific integrated circuit (ASIC), a digital signal processor (DSP), or combinations of such devices. As described herein, the term “processor” is meant to encompass a single processor or processing unit, multiple processors, multiple processing units, or other suitably configured computing element or elements.

The memory 132 can store electronic data that can be used by the head-mountable device 100. For example, the memory 132 can store electrical data or content such as, for example, audio and video files, documents and applications, device settings and user preferences, timing and control signals or data for the various modules, data structures or databases, and so on. The memory 132 can be configured as any type of memory. By way of example only, the memory 132 can be implemented as random access memory, read-only memory, Flash memory, removable memory, or other types of storage elements, or combinations of such devices.

The head-mountable device 100 can further include a display 140 for displaying visual information for a user. The display 140 can provide visual (e.g., image or video) output. The display 140 can be or include an opaque, transparent, and/or translucent display. The display 140 may have a transparent or translucent medium through which light representative of images is directed to a user's eyes. The display 140 may utilize digital light projection, OLEDs, LEDS, uLEDs, liquid crystal on silicon, laser scanning light source, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface. The head-mountable device 100 can include an optical subassembly configured to help optically adjust and correctly project the image-based content being displayed by the display 140 for close up viewing. The optical subassembly can include one or more lenses, mirrors, or other optical devices.

The head-mountable device 100 can include one or more sensors 170, as described herein. The head-mountable device 100 can include one or more other sensors. Such sensors can be configured to sense substantially any type of characteristic such as, but not limited to, images, pressure, light, touch, force, temperature, position, motion, and so on. For example, the sensor can be a photodetector, a temperature sensor, a light or optical sensor, an atmospheric pressure sensor, a humidity sensor, a magnet, a gyroscope, an accelerometer, a chemical sensor, an ozone sensor, a particulate count sensor, and so on. By further example, the sensor can be a bio-sensor for tracking biometric characteristics, such as health and activity metrics. Other user sensors can perform facial feature detection, facial movement detection, facial recognition, eye tracking, user mood detection, user emotion detection, voice detection, etc. Sensors can include a camera which can capture image based content of the outside world.

The head-mountable device 100 can include an input/output component 186, which can include any suitable component for connecting head-mountable device 100 to other devices. Suitable components can include, for example, audio/video jacks, data connectors, or any additional or alternative input/output components. The input/output component 186 can include buttons, keys, or another feature that can act as a keyboard for operation by the user.

The head-mountable device 100 can include the microphone 188 as described herein. The microphone 188 can be operably connected to the processor 130 for detection of sound levels and communication of detections for further processing, as described further herein.

The head-mountable device 100 can include one or more speakers 194. The speakers 194 can be operably connected to the processor 130 for control of audio output, including sound levels, as described further herein.

The head-mountable device 100 can include communications circuitry 192 for communicating with one or more servers or other devices using any suitable communications protocol. For example, communications circuitry 192 can support Wi-Fi (e.g., a 802.11 protocol), Ethernet, Bluetooth, high frequency systems (e.g., 900 MHZ, 2.4 GHZ, and 5.6 GHz communication systems), infrared, TCP/IP (e.g., any of the protocols used in each of the TCP/IP layers), HTTP, BitTorrent, FTP, RTP, RTSP, SSH, any other communications protocol, or any combination thereof. Communications circuitry 192 can also include an antenna for transmitting and receiving electromagnetic signals.

The head-mountable device 100 can include a battery, which can charge and/or power components of the head-mountable device 100. The battery can also charge and/or power components connected to the head-mountable device 100.

The head-mountable device 100 can include any one or more of the various electronic circuits 250, 350, and/or 450 described herein. It will be understood that such components can correspond to other features of the head-mountable device described herein.

Accordingly, embodiments of the present disclosure provide a head-mountable device with electronic circuits, such as cameras, sensors, and input/output devices. The head-mountable device can secure such electronic circuits with an assembly that also provides thermal dissipation, electrical grounding, and a sealed chamber to isolate the electronic circuit from ingress of debris. The assembly can provide a degree of mobility, where desired. Accordingly, the electronic circuit can operate more optimally and with lower risk of degradation and interference with other components of the head-mountable device.

Various examples of aspects of the disclosure are described below as clauses for convenience. These are provided as examples, and do not limit the subject technology.
Clause A: a head-mountable device comprising: a chassis; a bracket moveably coupled to the chassis; an electronic circuit mounted on the bracket on a first side of the electronic circuit; a cover on a second side of the electronic circuit, opposite the first side, the cover being coupled to the bracket adjacent to sides of the electronic circuit; and a thermally conductive medium extending from the cover to the second side of the electronic circuit.
Clause B: a head-mountable device comprising: a chassis defining a sealed chamber; a window at a first end of the chamber; a camera within the chamber; a flex circuit extending from the camera and out of the chamber; and a thermally conductive sheet against the camera, the flex circuit, and the chassis, the sheet forming a seal at a second side of the chamber.
Clause C: a head-mountable device comprising: a chassis defining a chamber; a camera within the chamber and having a first side and a second side, the first side contacting the chassis; an electrically conductive plate on the second side of the camera; and an elastic member biasing the plate against the first side of the camera.

One or more of the above clauses can include one or more of the features described below. It is noted that any of the following clauses may be combined in any combination with each other, and placed into a respective independent clause, e.g., clause A, B, or C.
Clause 1: the bracket comprises: an arm extending from a pivot, wherein the bracket is moveable about the pivot; and an end portion at an end of the arm and supporting the electronic circuit, wherein a thickness of the end portions is greater than a thickness of the arm.
Clause 2: the electronic circuit is a light projector.
Clause 3: the thermally conductive medium is a thermal gel.
Clause 4: the cover is a clad plate.
Clause 5: the clad plate comprises copper clad with stainless steel.
Clause 6: the cover is a thermally conductive graphite sheet.
Clause 7: the sheet contacts the chassis on opposing sides of the camera.
Clause 8: a processor operably connected to the camera by the flex circuit.
Clause 9: the sheet comprises a woven fabric.
Clause 10: the thermally conductive sheet comprises a material having a thermal conductivity of at least 300 W/(m·K)
Clause 11: the first side of the camera is electrically connected to ground via the chassis and the second side of the camera is electrically connected to ground via the plate.
Clause 12: the elastic member further biases the plate against the chassis.
Clause 13: the chassis comprises a first chassis portion, the head-mountable device further comprising a second chassis portion coupled to the first chassis portion, a portion of the elastic member and a portion of the plate being between the first chassis portion and the second chassis portion.
Clause 14: the elastic member comprises foam.
Clause 15: the electrically conductive plate comprises copper.
Clause 16: the plate and the elastic member each have an annular shape to form a channel extending entirely through the plate and the elastic member, wherein a portion of the camera extends into the channel.
Clause 17: a window on a side of the camera that is opposite the chassis, wherein the chamber is a sealed chamber formed in part by the window.

As described herein, aspects of the present technology can include the gathering and use of data. The present disclosure contemplates that in some instances, gathered data can include personal information or other data that uniquely identifies or can be used to locate or contact a specific person. The present disclosure contemplates that the entities responsible for the collection, analysis, disclosure, transfer, storage, or other use of such personal information or other data will comply with well-established privacy practices and/or privacy policies. The present disclosure also contemplates embodiments in which users can selectively block the use of or access to personal information or other data (e.g., managed to minimize risks of unintentional or unauthorized access or use).

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the invention. The word exemplary is used to mean serving as an example or illustration. To the extent that the term include, have, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, and systems can generally be integrated together in a single software/hardware product or packaged into multiple software/hardware products.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. $112, sixth paragraph, unless the element is expressly recited using the phrase “means for” or, in the case of a method claim, the element is recited using the phrase “step for”.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language of the claims and to encompass all legal equivalents. Notwithstanding, none of the claims are intended to embrace subject matter that fails to satisfy the requirements of the applicable patent law, nor should they be interpreted in such a way.

What is claimed is:

1. A head-mountable device comprising:
a chassis;
a bracket moveably coupled to the chassis;
an electronic circuit mounted on the bracket on a first side of the electronic circuit;
a cover on a second side of the electronic circuit, opposite the first side, the cover being coupled to the bracket adjacent to sides of the electronic circuit; and
a thermally conductive medium extending from the cover to the second side of the electronic circuit.

2. The head-mountable device of claim 1, wherein the bracket comprises:
an arm extending from a pivot, wherein the bracket is moveable about the pivot; and
an end portion at an end of the arm and supporting the electronic circuit, wherein a thickness of the end portions is greater than a thickness of the arm.

3. The head-mountable device of claim 1, wherein the electronic circuit is a light projector.

4. The head-mountable device of claim 1, wherein the thermally conductive medium is a thermal gel.

5. The head-mountable device of claim 1, wherein the cover is a clad plate.

6. The head-mountable device of claim 5, wherein the clad plate comprises copper clad with stainless steel.

7. The head-mountable device of claim 1, wherein the cover is a thermally conductive graphite sheet.

8. A head-mountable device comprising:
a chassis defining a sealed chamber;
a window at a first end of the chamber;
a camera within the chamber;
a flex circuit extending from the camera and out of the chamber; and
a thermally conductive sheet against the camera, the flex circuit, and the chassis, the sheet forming a seal at a second side of the chamber.

9. The head-mountable device of claim 8, wherein the sheet contacts the chassis on opposing sides of the camera.

10. The head-mountable device of claim 8, further comprising a processor operably connected to the camera by the flex circuit.

11. The head-mountable device of claim 8, wherein the sheet comprises a woven fabric.

12. The head-mountable device of claim 8, wherein the thermally conductive sheet comprises a material having a thermal conductivity of at least 300 W/(m·K).

13. A head-mountable device comprising:
a chassis defining a chamber;
a camera within the chamber and having a first side and a second side, the first side contacting the chassis;
an electrically conductive plate on the second side of the camera; and
an elastic member biasing the plate against the first side of the camera.

14. The head-mountable device of claim 13, wherein the first side of the camera is electrically connected to ground via the chassis and the second side of the camera is electrically connected to ground via the plate.

15. The head-mountable device of claim 13, wherein the elastic member further biases the plate against the chassis.

16. The head-mountable device of claim 13, wherein the chassis comprises a first chassis portion, the head-mountable device further comprising a second chassis portion coupled to the first chassis portion, a portion of the elastic member and a portion of the plate being between the first chassis portion and the second chassis portion.

17. The head-mountable device of claim 13, wherein the elastic member comprises foam.

18. The head-mountable device of claim 13, wherein the electrically conductive plate comprises copper.

19. The head-mountable device of claim 13, wherein the plate and the elastic member each have an annular shape to form a channel extending entirely through the plate and the elastic member, wherein a portion of the camera extends into the channel.

20. The head-mountable device of claim 13, further comprising a window on a side of the camera that is opposite the chassis, wherein the chamber is a sealed chamber formed in part by the window.
